(19) United States
(12) Patent Application Publication
(10) Pub. No.: US 2021/0098749 A1
(43) Pub. Date: Apr. 1, 2021

(54) DISPLAY APPARATUS AND METHOD OF REPAIRING DISPLAY APPARATUS

(71) Applicant: Samsung Display Co., Ltd., Yongin-si (KR)

(72) Inventors: Moonkeun CHOI, Yongin-si (KR); Seungjoo CHOI, Yongin-si (KR); Jungouck AHN, Yongin-si (KR); Yongsuk CHOI, Yongin-si (KR)

(73) Assignee: Samsung Display Co., Ltd., Yongin-si (KR)

(21) Appl. No.: 16/915,174

(22) Filed: Jun. 29, 2020

(30) Foreign Application Priority Data
Sep. 26, 2019 (KR) 10-2019-0119094

(51) Int. Cl. H01L 51/56; H01L 27/32; H01L 51/00

(52) U.S. Cl. CPC H01L 51/56; H01L 27/3258; H01L 2251/568; H01L 51/0031; H01L 27/3279

(57) ABSTRACT

A display apparatus includes a substrate including a display area and a non-display area, a display element over the display area, a thin film transistor disposed between the substrate and the display element and connected to the display element, a first wire connected to the thin film transistor and extending in a first direction, and a second wire disposed above the first wire and extending in a second direction crossing the first direction. The display apparatus includes a connection conductive layer overlapping a cross portion where the first wire and the second wire cross each other, an insulating layer between the connection conductive layer and the second wire, and at least one connection contact hole defined in the insulating layer, the at least one connection contact hole connecting the connection conductive layer to the second wire.

### CROSS-REFERENCE TO RELATED APPLICATION

This application claims priority to and benefits of Korean Patent Application No. 10-2019-0119094 under 35 U.S.C. § 119, filed in the Korean Intellectual Property Office on Sep. 26, 2019, the entire contents of which are incorporated herein by reference.

### BACKGROUND

### 1. Technical Field

One or more embodiments relate to a display apparatus for implementing high resolution and improved reliability and a method of repairing the display apparatus.

### 2. Description of the Related Art

As information society continues to develop, demand for display apparatuses of various types has been increasing. The field of display apparatuses has rapidly focused on flat panel display (FPD) devices, which are thin, light, and capable of a large display area, FPD devices replacing cathode ray tube (CRT) devices having a relatively large volume. Examples of FPD devices include a liquid crystal display (LCD) device, a plasma display panel (PDP), an organic light-emitting diode (OLED) display, and an electrophoretic display (EPD) device.

Such display apparatuses may include a substrate including a display area and a non-display area, and various wires capable of transferring electrical signals to the display area may be included.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

One or more embodiments include a highly reliable display apparatus.

Additional aspects will be set forth in part in the description which follows and, in part, will be apparent from the description, or may be learned by practice of the presented embodiments of the disclosure.

According to one or more embodiments, a display apparatus may include a substrate including a display area and a non-display area, a display element over the display area, a thin film transistor disposed between the substrate and the display element and connected to the display element, a first wire connected to the thin film transistor and extending in a first direction, a second wire disposed above the first wire and extending in a second direction crossing the first direction, a connection conductive layer overlapping a cross portion where the first wire and the second wire may cross each other, an insulating layer disposed between the connection conductive layer and the second wire, and at least one connection contact hole defined in the insulating layer, the at least one connection contact hole connecting the connection conductive layer and the second wire.

The connection conductive layer may be between the substrate and the first wire.

A buffer layer may be disposed between the connection conductive layer and the first wire.

The display apparatus may further include a bias electrode disposed between the substrate and a semiconductor layer and overlapping the semiconductor layer, wherein the thin film transistor includes the semiconductor layer, and the connection conductive layer and the bias electrode may be disposed on a same layer.

The connection conductive layer may be spaced apart from the bias electrode.

The connection conductive layer may be disposed over the second wire.

The display element may include a pixel electrode and an opposite electrode and the connection conductive layer and the pixel electrode are disposed on a same layer.

The connection conductive layer may be spaced apart from the pixel electrode.

The display apparatus may further include a planarization layer between the display element and the thin film transistor, wherein the connection conductive layer may be on the planarization layer.

The thin film transistor may include a gate electrode, a source electrode, and a drain electrode, wherein the first wire may be connected to the gate electrode.

The second wire may be connected to the source electrode or the drain electrode.

The connection conductive layer may extend in the second direction.

The connection conductive layer may include an island shape.

A length of the connection conductive layer in the second direction may be greater than a length the cross portion in the second direction.

The at least one connection contact hole may include a first contact hole and a second contact hole, wherein the cross portion may be between the first contact hole and the second contact hole.

The second wire may include a data line.

The display apparatus may further include an inorganic protection layer covering the second wire.

According to one or more embodiments, a method of repairing a display apparatus, wherein the display apparatus may include a substrate, a first wire extending over the substrate in a first direction, a second wire disposed above the first wire and crossing the first wire, a connection conductive layer overlapping a cross portion where the first wire and the second wire may cross each other, an insulating layer between the connection conductive layer and the second wire, and at least one connection contact hole in the insulating layer, the connection conductive layer is connected to the second wire via the at least one connection contact hole, wherein the method may include cutting the second wire by irradiating laser to an area between the cross portion and the at least one connection contact hole.

The method may further include before the cutting of the second wire, testing whether the first wire and the second wire may be short-circuited or not.

The display apparatus may further include a display element including a pixel electrode and an opposite electrode, wherein the method may further include, after the cutting of the second wire, connecting the second wire by forming the connection conductive layer and the pixel electrode on a same layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to an embodiment;

FIG. 2 is an equivalent circuit diagram showing a pixel of a display apparatus according to an embodiment;

FIG. 3 is a schematic representation illustrating locations of thin film transistors and a capacitor included in a pixel circuit according to an embodiment;

FIG. 4 is a schematic cross-sectional view taken along line A-A′ of FIG. 3 showing a structure in which an organic light-emitting diode may be included;

FIG. 5 is a schematic cross-sectional view taken along line B-B′ of FIG. 3;

FIG. 6A is a flowchart showing a method of repairing a display apparatus, according to an embodiment;

FIG. 6B is a schematic cross-sectional view showing an operation of testing whether a first wire and a second wire may be short-circuited or not, according to an embodiment;

FIG. 6C is a schematic enlarged view showing an operation of cutting a second wire, according to an embodiment;

FIG. 7 is a schematic representation illustrating locations of thin film transistors and a capacitor included in a pixel circuit according to another embodiment;

FIG. 8 is a schematic representation illustrating locations of thin film transistors and a capacitor included in a pixel circuit according to another embodiment;

FIG. 9 is a schematic cross-sectional view taken along line C-C′ of FIG. 8;

FIG. 10A is a flowchart showing a method of repairing a display apparatus, according to another embodiment;

FIG. 10B is a schematic cross-sectional view showing an operation of cutting a second wire, according to another embodiment;

FIG. 10C is a schematic cross-sectional view showing an operation of forming a connection conductive layer, according to another embodiment; and

FIG. 11 is a schematic representation illustrating locations of thin film transistors and a capacitor included in a pixel circuit according to another embodiment.

### DETAILED DESCRIPTION OF THE EMBODIMENTS

Reference will now be made in detail to embodiments, examples of which are illustrated in the accompanying drawings, wherein like reference numerals refer to like elements throughout. Repeated description of like elements may be omitted. Embodiments may have different forms and should not be construed as being limited to the descriptions set forth herein. Accordingly, embodiments are merely described below, by referring to the figures, to explain aspects of the description.

As used herein, the term “and/or” includes any and all combinations of one or more of the associated listed items. The terms “and” and “or” may be used in the conjunctive or disjunctive sense and may be understood to be equivalent to “and/or.” Throughout the disclosure, the expression “at least one of a, b and c” indicates only a, only b, only c, both a and b, both a and c, both b and c, all of a, b, and c, or variations thereof.

While such terms as “first” and “second” may be used to describe various components, such components must not be limited to the above terms. The above terms are used only to distinguish one component from another. Similarly, spatially relative terms, such as “beneath”, “below”, “lower”, “above”, and “upper”, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

The singular forms “a,” “an,” and “the” as used herein are intended to include the plural forms as well, unless the context clearly indicates otherwise.

It will be understood that the terms “comprise,” “comprising,” “include”, “including”, “has”, and/or “having” as used herein specify the presence of stated features or components, but do not preclude the presence or addition of one or more other features or components.

It will be further understood that, when a layer, region, or component is referred to as being “on” another layer, region, or component, it can be directly or indirectly on the other layer, region, or component. For example, intervening layers, regions, or components may be present.

Sizes of components in the drawings may be exaggerated or reduced for convenience of explanation. For example, since sizes and thicknesses of components in the drawings are arbitrarily illustrated for convenience of explanation, the disclosure is not limited thereto.

When an embodiment may be implemented differently, a certain process order may be performed differently from the described order. For example, two consecutively described processes may be performed substantially at the same time or performed in an order opposite to the described order.

It will be further understood that, when layers, regions, or components are referred to as being “connected” to each other, they may be “directly connected” to each other or may be “indirectly connected” to each other with intervening layers, regions, or components therebetween. For example, when layers, regions, or components are referred to as being “electrically connected” to each other, they may be “directly electrically connected” to each other or may be “indirectly electrically connected” to each other with intervening layers, regions, or components therebetween.

The term “overlap” may include layer, stack, face or facing, extending over (or under), covering or partly covering (or being covered or partly covered) or any other suitable term as would be appreciated and understood by those of ordinary skill in the art.

Unless otherwise defined, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

A display apparatus may be an apparatus for displaying an image, and examples of a display apparatus may include a liquid crystal display apparatus, an electrophoretic display apparatus, an organic light-emitting display apparatus, an inorganic light-emitting display apparatus, a field emission display apparatus, a surface-conduction electron-emitter display apparatus, a quantum dot display apparatus, a plasma display apparatus, and a cathode ray tube display apparatus. Although an organic light-emitting display apparatus is described below as an example, embodiments may be applied to various display apparatuses such as those described above.

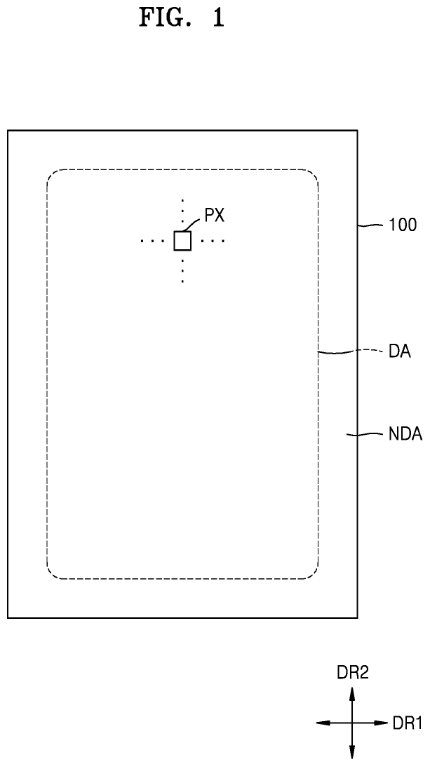

FIG. 1 is a schematic plan view of a display apparatus according to an embodiment.

Referring to FIG. 1, the display apparatus may include a display area DA and a non-display area NDA around the display area DA. Pixels PX including display elements may be disposed over the display area DA to provide an image.

A pixel PX may emit a color light, for example, red, green, blue, or white light, and as an example, may include an organic light-emitting diode. A pixel PX may further include devices such as a thin film transistor (TFT) and a capacitor.

A pixel PX described herein refers to a sub-pixel that may emit light, such as red light, green light, blue light, or white light, as described above.

A non-display area NDA may be an area where no image may be provided. Controllers such as a scan driver and a data driver (or a pad portion to which a printed circuit board on which the controllers may be mounted) may be disposed over the non-display area NDA. The controllers may provide electrical signals that may be applied to pixels PX of the display area DA.

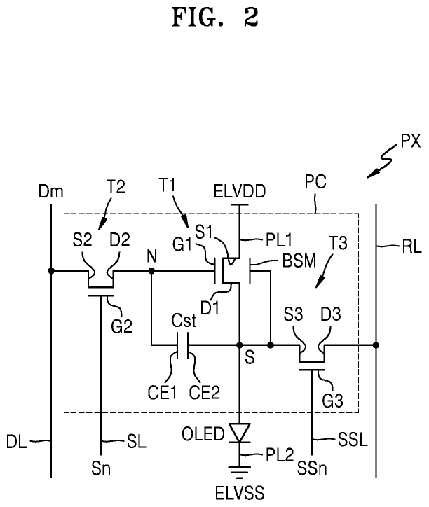

FIG. 2 is an equivalent circuit diagram showing a pixel PX of a display apparatus according to an embodiment.

Referring to FIG. 2, a pixel PX may include an organic light-emitting diode OLED and a pixel circuit PC including TFTs for driving the organic light-emitting diode OLED. The pixel circuit PC may include a driving TFT T1, a switching TFT T2, a sensing TFT T3, and a storage capacitor Cst.

In one or more embodiments, a pixel circuit PC may include three TFTs, for example, the driving TFT T1, the switching TFT T2, and the sensing TFT T3, and a storage capacitor Cst. However, in another embodiment, the number of TFTs and storage capacitors included in the pixel circuit PC or a structure of the pixel circuit PC may be modified.

A scan line SL may be connected to a gate electrode G2 of the switching TFT T2, a data line DL may be connected to a source electrode S2, and a first electrode CE1 of the storage capacitor Cst may be connected to a drain electrode D2.

Accordingly, the switching TFT T2 may supply a data voltage of the data line DL to a first node N in response to a scan signal Sn from the scan line SL of each pixel PX.

A gate electrode G1 of the driving TFT T1 may be connected to the first node N, a source electrode S1 may be connected to a first power line PL1 for transferring a driving power voltage ELVDD, and a drain electrode D1 may be connected to an anode of the organic light-emitting diode OLED.

Accordingly, the driving TFT T1 may adjust an amount of current flowing through the organic light-emitting diode OLED according to a source-gate voltage of its own. For example, the driving TFT T1 may adjust an amount of current according to a voltage that may be applied between the driving power voltage ELVDD and the first node N.

A sensing control line SSL may be connected to a gate electrode G3 of the sensing TFT T3, a source electrode S3 may be connected to a second node S, and a drain electrode D3 may be connected to a reference voltage line RL. In some embodiments, the sensing TFT T3 may be controlled by the scan line SL instead of the sensing control line SSL.

The sensing TFT T3 may sense the potential of the anode of the organic light-emitting diode OLED. The sensing TFT T3 may supply a pre-charging voltage from the reference voltage line RL to the second node S in response to a sensing signal SSn from the sensing control line SSL or may supply a voltage of the anode of the organic light-emitting diode OLED to the reference voltage line RL during a sensing period.

The storage capacitor Cst may have the first electrode CE1 connected to the first node N and a second electrode CE2 connected to the second node S. The storage capacitor Cst may charge a difference voltage between voltages that may be supplied to the first and second nodes N and S, respectively, and may supply the difference voltage as a driving voltage of the driving TFT T1. For example, the storage capacitor Cst may charge a difference voltage between a data voltage and a pre-charging voltage, which may be supplied to the first and second nodes N and S, respectively.

A bias electrode BSM may be formed to correspond to the driving TFT T1 and be connected to the source electrode S3 of the sensing TFT T3. Because the bias electrode BSM may receive a voltage interlocked with the potential of the source electrode S3 of the sensing TFT T3, the driving TFT T1 may be stabilized. In some embodiments, the bias electrode BSM may not be connected to the source electrode S3 of the sensing TFT T3 but may be connected to a separate bias wire.

An opposite electrode (for example, a cathode) of the organic light-emitting diode OLED may receive a common power voltage ELVSS. The organic light-emitting diode OLED may receive a driving current from the driving TFT T1 and emit light.

FIG. 2 shows a pixel PX including signal lines, for example, the scan line SL, the sensing control line SSL, the data line DL, the reference voltage line RL, the first power line PL1, and a second power line PL2. However, in another embodiment, at least one of the signal lines, for example, the scan line SL, the sensing control line SSL, the data line DL, the reference voltage line RL, the first power line PL1, and the second power line PL2 may be shared among neighboring pixels.

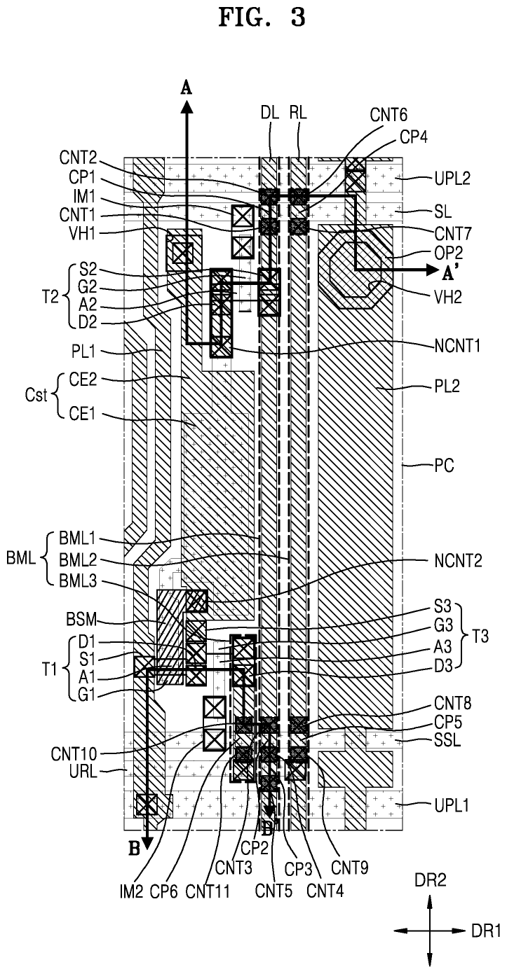

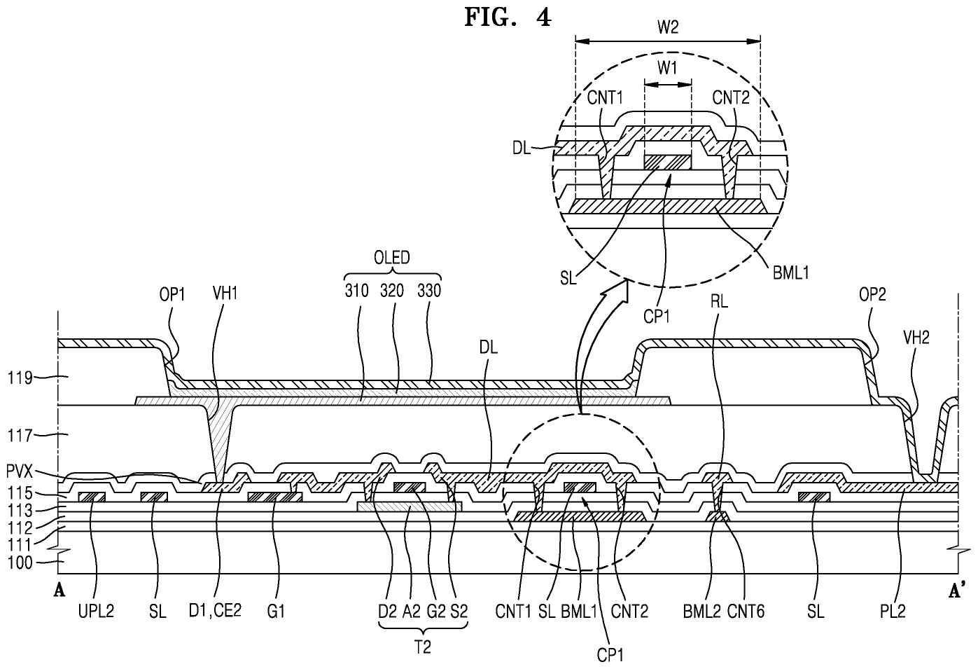

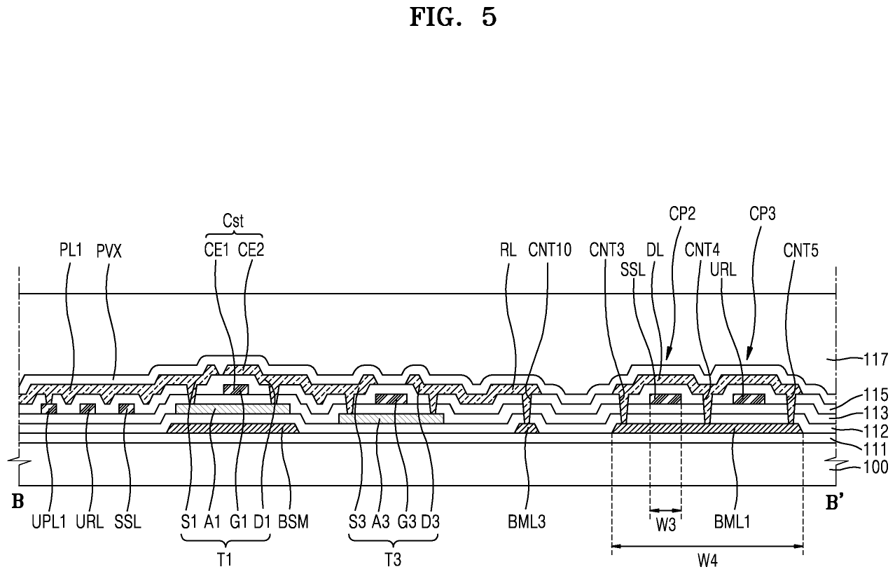

FIG. 3 is a schematic representation illustrating locations of TFTs and a capacitor Cst included in a pixel circuit PC according to an embodiment. FIG. 4 is a schematic cross-sectional view taken along line A-A′ of FIG. 3 showing a structure in which the organic light-emitting diode OLED may be included. FIG. 5 is a schematic cross-sectional view taken along line B-B′ of FIG. 3.

Referring to FIG. 3, the pixel circuit PC of a display apparatus according to an embodiment may be connected to the scan line SL, the sensing control line SSL, a first lower power line UPL1, a second lower power line UPL2, and a lower reference voltage line URL extending in a first direction DR1.

Also, the pixel circuit PC may be connected to the data line DL, the reference voltage line RL, the first power line PL1, the second power line PL2, and a connection conductive layer BML extending in a second direction DR2 crossing the first direction DR1.

In an embodiment, the scan line SL, the sensing control line SSL, the first lower power line UPL1, and the second lower power line UPL2 may be disposed on the same layer as one another. The data line DL, the reference voltage line RL, the first power line PL1, and the second power line PL2 may be disposed on the same layer as one another and may be disposed with the scan line SL, etc. and an interlayer insulating layer 115 (refer to FIG. 4) therebetween. In another embodiment, the first power line PL1 and the second power line PL2 may be disposed on a different layer from the data line DL. However, for convenience of description, a case where the first power line PL1 and the second power line PL2 may be disposed on the same layer as the data line DL will be described in detail below.

In an embodiment, the lower reference voltage line URL may be disposed on the same layer as the scan line SL. In another embodiment, the lower reference voltage line URL may be disposed on the same layer as a semiconductor layer. A case where the lower reference voltage line URL may be disposed on the same layer as the scan line SL will be described in detail below.

In the specification, the scan line SL, the sensing control line SSL, the first lower power line UPL1, the second lower power line UPL2, or the lower reference voltage line URL extending in the first direction DR1 may be referred to as a first wire. The data line DL, the reference voltage line RL, the first power line PL1, or the second power line PL2 may be referred to as a second wire.

The pixel circuit PC may include the driving TFT T1, the switching TFT T2, the sensing TFT T3, and the storage capacitor Cst.

Semiconductor layers A1, A2, and A3 of the driving TFT T1, the switching TFT T2, and the sensing TFT T3 may be disposed on the same layer as one another and may include the same material as one another. For example, the semiconductor layers A1, A2, and A3 may include amorphous silicon or polysilicon. Also, the semiconductor layers A1, A2, and A3 may include an oxide semiconductor material including oxide of at least one material selected from the group including indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). In some embodiments, the semiconductor layers A1, A2, and A3 may include Zn oxide, In—Zn oxide, Ga—In—Zn oxide, etc., which may be Zn oxide-based materials. In some embodiments, the semiconductor layers A1, A2, and A3 may include an IGZO (In—Ga—Zn—O), ITZO (In—Sn—Zn—O), or IGTZO (In—Ga—Sn—Zn—O) semiconductor having metal, such as indium (In), gallium (Ga), and stannum (Sn), contained in ZnO. The semiconductor layers A1, A2, and A3 may have a single-layer or multilayer structure.

The semiconductor layers A1, A2, and A3 may each include a channel region and a source region and a drain region on sides of the channel region. The source region and the drain region may be regions having a concentration of carriers adjusted. For example, in case that the semiconductor layers A1, A2, and A3 include silicon, the source region and the drain region may be doped with impurities. As another example, in case that the semiconductor layers A1, A2, and A3 include an oxide semiconductor, the source region and the drain region may be regions having a carrier concentration increased by plasma processing.

The gate electrodes G1, G2, and G3 may overlap the channel region of the semiconductor layers A1, A2, and A3 with a gate insulating layer 113 (refer to FIG. 4) therebetween. The source electrodes S1, S2, and S3 and the drain electrodes D1, D2, and D3 may be disposed on the interlayer insulating layer 115 and may be connected to the source region and the drain region via contact holes.

The gate electrode G1 of the driving TFT T1 may have an island shape (e.g., may be spaced apart from another feature). The gate electrode G1 may serve not only as a gate electrode of the driving TFT T1 but also as the first electrode CE1 of the storage capacitor Cst. In an embodiment, the gate electrode G1 may be integrally formed with the first electrode CE1 of the storage capacitor Cst. A portion of the gate electrode G1 may overlap the semiconductor layer A1 of the driving TFT T1, and a portion of the gate electrode G1 may overlap the second electrode CE2 of the storage capacitor Cst to form a first capacitance. In another embodiment, the first electrode CE1 of the storage capacitor Cst may extend from the gate electrode G1 overlapping the semiconductor layer A1 of the driving TFT T1.

The bias electrode BSM may be disposed below the driving TFT T1 to correspond to the gate electrode G1 (e.g., the first electrode CE1 of the storage capacitor Cst). Accordingly, the first electrode CE1 and the bias electrode BSM may form a second capacitance. Also, an end of the gate electrode G1 may be connected to the drain electrode D2 of the switching TFT T2 via a first node contact hole NCNT1.

In an embodiment, the gate electrode G2 of the switching TFT T2 and the scan line SL may be connected to each other via a first intermediate conductive layer IM1. For example, as shown in FIG. 3, the first intermediate conductive layer IM1 may be disposed on the same layer as the data line DL and may be connected to the gate electrode G2 of the switching TFT T2 and the scan line SL, respectively, via contact holes. In another embodiment, the gate electrode G2 of the switching TFT T2 may be a portion of the scan line SL. For example, the gate electrode G2 may be an area protruding from the scan line SL in the second direction DR2, the scan line SL extending in the first direction DR1. Accordingly, the scan signal Sn that the scan line SL may transfer may be transferred to the gate electrode G2, and in response to the scan signal Sn, the switching TFT T2 may operate.

In an embodiment, the gate electrode G3 of the sensing TFT T3 and the sensing control line SSL may be connected to each other via a second intermediate conductive layer IM2. For example, the second intermediate conductive layer IM2 may be disposed on the same layer as the data line DL and may be connected to the gate electrode G3 of the sensing TFT T3 and the sensing control line SSL, respectively, via contact holes. In another embodiment, the gate electrode G3 of the sensing TFT T3 may be a portion of the sensing control line SSL. For example, the sensing control line SSL may overlap the semiconductor layer A3 of the sensing TFT T3, and the overlapping area may serve as the gate electrode G3. Accordingly, the sensing signal SSn that the sensing control line SSL may transfer may be transferred to the gate electrode G3, and in response to the sensing signal SSn, the sensing TFT T3 may operate.

The drain electrode D1 of the driving TFT T1 may be integrally provided with the second electrode CE2 of the storage capacitor Cst and the source electrode S3 of the sensing TFT T3 and may also be connected to the bias electrode BSM via a second node contact hole NCNT2. The source electrode S1 of the driving TFT T1 may be connected to the first power line PL1 via a contact hole.

The source electrode S2 of the switching TFT T2 may be a portion of the data line DL and thus may transfer the data signal Dm of the data line DL to the source region of the switching TFT T2. An end of the drain electrode D2 of the switching TFT T2 may be connected to the first electrode CE1 of the storage capacitor Cst via the first node contact hole NCNT1.

The source electrode S3 of the sensing TFT T3 may be connected to the drain electrode D1 of the driving TFT T1, and the drain electrode D3 may correspond to the drain region of the semiconductor layer A3 of the sensing TFT T3. The drain electrode D3 may be connected to the lower reference voltage line URL via a contact hole. The lower reference voltage line URL may be connected to the reference voltage line RL via a contact hole.

The first electrode CE1 of the storage capacitor Cst may be integrally formed with the gate electrode G1, and the second electrode CE2 may overlap the first electrode CE1 with the interlayer insulating layer 115 (refer to FIG. 5) therebetween. The second electrode CE2 of the storage capacitor Cst may be connected to a pixel electrode 310 (refer to FIG. 4) of the organic light-emitting diode OLED via a first via hole VH1.

Below the first electrode CE1 of the storage capacitor Cst, the bias electrode BSM may be disposed between a first buffer layer 111 (refer to FIG. 5) and a second buffer layer 112 (refer to FIG. 5). Accordingly, the bias electrode BSM and the first electrode CE1 of the storage capacitor Cst may form a second capacitance. Because an end of the bias electrode BSM may be connected to the source electrode S3 of the sensing TFT T3 via the second node contact hole NCNT2, a voltage that may be applied to the source electrode S3 may be applied to the bias electrode BSM in an interlocking manner. In another embodiment, a separate bias voltage may be provided to the bias electrode BSM, or no voltage may be applied to the bias electrode BSM.

The first power line PL1 and the second power line PL2 may extend in the second direction DR2 on the same layer. The first power line PL1 and the second power line PL2 may be voltage lines for transferring different voltages from each other, and the first power line PL1 may transfer the driving power voltage ELVDD and the second power line PL2 may transfer the common power voltage ELVSS.

The first power line PL1 may be connected to the first lower power line UPL1 extending in the first direction DR1 via a contact hole. By the first lower power line UPL1 extending in the first direction DR1 and the first power line PL1 extending in the second direction DR2, the driving power voltage ELVDD may be provided in a mesh structure.

The second power line PL2 may be connected to the second lower power line UPL2 extending in the first direction DR1 via a contact hole. By the second lower power line UPL2 extending in the first direction DR1 and the second power line PL2 extending in the second direction DR2, the common power voltage ELVSS may be provided in a mesh structure.

The first power line PL1 may be connected to the source electrode S1 of the driving TFT T1 via a contact hole. The second power line PL2 may be connected to an opposite electrode 330 (refer to FIG. 4) of the organic light-emitting diode OLED via a second via hole VH2.

In an embodiment, the connection conductive layer BML may be disposed below the first wire. For example, the connection conductive layer BML may be disposed below the scan line SL, the sensing control line SSL, or the lower reference voltage line URL. Specifically, the connection conductive layer BML may be disposed between a substrate 100 and the first wire.

In an embodiment, the connection conductive layer BML may be disposed on the same layer as the bias electrode BSM. For example, the connection conductive layer BML may be disposed between the first buffer layer 111 and the second buffer layer 112. In another embodiment, the connection conductive layer BML may be disposed between the substrate 100 and the first buffer layer 111. The connection conductive layer BML may be spaced apart from the bias electrode BSM. Specifically, the connection conductive layer BML may be spaced apart from the bias electrode BSM in the first direction DR1 or the second direction DR2.

In an embodiment, the connection conductive layer BML may include a first connection conductive layer BML1, a second connection conductive layer BML2, and a third connection conductive layer BML3. The first connection conductive layer BML1, the second connection conductive layer BML2, and the third connection conductive layer BML3 may be spaced apart from one another. For example, the first connection conductive layer BML1, the second connection conductive layer BML2, and the third connection conductive layer BML3 may be spaced apart from one another in the first direction DR1.

The first connection conductive layer BML1 may overlap the data line DL. In an embodiment, the first connection conductive layer BML1 may extend in the second direction DR2 while overlapping the data line DL. For example, the first connection conductive layer BML1 may extend while continuously overlapping the data line DL.

In an embodiment, the first connection conductive layer BML1 may overlap a first cross portion CP1 where the data line DL and the scan line SL may cross each other. The first connection conductive layer BML1 may overlap a second cross portion CP2 where the data line DL and the sensing control line SSL may cross each other. Also, the first connection conductive layer BML1 may overlap a third cross portion CP3 where the data line DL and the lower reference voltage line URL may cross each other.

The first connection conductive layer BML1 may be connected to the data line DL via at least one connection contact hole. In an embodiment, the first connection conductive layer BML1 may be connected to the data line DL via a first contact hole CNT1 and a second contact hole CNT2. In this regard, the first cross portion CP1 may be disposed between the first contact hole CNT1 and the second contact hole CNT2. Accordingly, a data signal of the data line DL may be transferred by taking a detour (e.g., an alternative connective route or path) via the first connection conductive layer BML1. As another example, the first connection conductive layer BML1 may be connected to the data line DL via a third contact hole CNT3, a fourth contact hole CNT4, or a fifth contact hole CNT5. In this regard, the second cross portion CP2 may be disposed between the third contact hole CNT3 and the fourth contact hole CNT4. The third cross portion CP3 may be disposed between the fourth contact hole CNT4 and the fifth contact hole CNT5.

In another embodiment, some of the first to fifth contact holes CNT1 to CNT5 may be omitted. For example, the fourth contact hole CNT4 from among the third contact hole CNT3, the fourth contact hole CNT4, and the fifth contact hole CNT5 may be omitted. In another embodiment, a contact hole may be further included between the third contact hole CNT3 and the fourth contact hole CNT4.

The second connection conductive layer BML2 may overlap the reference voltage line RL. In an embodiment, the second connection conductive layer BML2 may extend in the second direction DR2 while overlapping the reference voltage line RL. For example, the second connection conductive layer BML2 may extend while continuously overlapping the reference voltage line RL.

In an embodiment, the second connection conductive layer BML2 may overlap a fourth cross portion CP4 where the reference voltage line RL and the scan line SL may cross each other. Also, the second connection conductive layer BML2 may overlap a fifth cross portion CP5 where the reference voltage line RL and the sensing control line SSL may cross each other.

The second connection conductive layer BML2 may be connected to the reference voltage line RL via at least one connection contact hole. For example, the second connection conductive layer BML2 may be connected to the reference voltage line RL via a sixth contact hole CNT6 or a seventh contact hole CNT7. In this regard, the fourth cross portion CP4 may be disposed between the sixth contact hole CNT6 and the seventh contact hole CNT7. As another example, the second connection conductive layer BML2 may be connected to the reference voltage line RL via an eighth contact hole CNT8 or a ninth contact hole CNT9. In this regard, the fifth cross portion CP5 may be disposed between the eighth contact hole CNT8 and the ninth contact hole CNT9. Accordingly, a pre-charging voltage of the reference voltage line RL may be transferred by taking a detour via the second connection conductive layer BML2.

The third connection conductive layer BML3 may overlap the second intermediate conductive layer IM2. In an embodiment, the third connection conductive layer BML3 may extend in the second direction DR2 while overlapping the second intermediate conductive layer IM2. For example, the third connection conductive layer BML3 may extend while continuously overlapping the second intermediate conductive layer IM2. The third connection conductive layer BML3 may overlap a sixth cross portion CP6 where the second intermediate conductive layer IM2 and the sensing control line SSL may cross each other.

The third connection conductive layer BML3 may be connected to the second intermediate conductive layer IM2 via at least one connection contact hole. For example, the third connection conductive layer BML3 may be connected to the second intermediate conductive layer IM2 via a tenth contact hole CNT10 or an eleventh contact hole CNT11. In this regard, the sixth cross portion CP6 may be disposed between the tenth contact hole CNT10 and the eleventh contact hole CNT11. Accordingly, a pre-charging voltage of the reference voltage line RL may be transferred by taking a detour via the third connection conductive layer BML3.

The connection conductive layer BML overlapping the second wire may be provided as described above to cut the second wire in case that the first wire and the second wire may be short-circuited. In case that the first wire and the second wire may be short-circuited, a cross portion where the first wire and the second wire may cross each other may be cut. In this regard, in case that the second wire may not have a mesh structure as the first power line PL1 or the second power line PL2 does, no signal may be transferred to the pixel circuit PC. In an embodiment, the connection conductive layer BML overlapping the second wire may be provided, and thus, even in case that the cross portion is cut, signals may be transferred to the pixel circuit PC. Specifically, the second wire and the connection conductive layer BML may be connected to each other via at least one contact hole, and thus, a signal may take a detour.

In an embodiment, the connection conductive layer BML may be formed simultaneously with the bias electrode BSM, and thus, no mask may additionally be used. Also, the connection conductive layer BML may decrease resistance of the second wire.

In a display apparatus according to one or more embodiments, pixel circuits PC having the same shape described with reference to FIG. 3 may be disposed in parallel in the first direction DR1 and the second direction DR2. In another embodiment, the pixel circuit PC included in a display apparatus may have a shape symmetric to that of a pixel circuit adjacent thereto.

Hereinafter, a stacking order for a structure of a display apparatus according to an embodiment will be described with reference to FIGS. 4 and 5.

Referring to FIG. 4, the substrate 100, the organic light-emitting diode OLED, which may be a display element disposed over the substrate 100, the switching TFT T2, the interlayer insulating layer 115 covering the gate electrode G2 of the switching TFT T2, and the data line DL, the reference voltage line RL, and the second power line PL2 on the interlayer insulating layer 115 may be disposed in at least one pixel included in a display apparatus according to an embodiment. In this regard, the first connection conductive layer BML1 may be disposed at the first cross portion CP1 where the data line DL and the scan line SL may cross each other, and the first connection conductive layer BML1 may be connected to the data line DL via the first contact hole CNT1 or the second contact hole CNT2. Also, the second connection conductive layer BML2 may be disposed at a fourth cross portion (not shown) where the reference voltage line RL and the scan line SL may cross each other, and the second connection conductive layer BML2 may be connected to the reference voltage line RL via the sixth contact hole CNT6.

The substrate 100 may include glass, ceramic, metal, a flexible or bendable material, or a combination thereof. In case that the substrate 100 is flexible or bendable, the substrate 100 may include polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a single-layer or multilayer structure of the material described above, and in a multilayer structure, the substrate 100 may further include an inorganic layer. In some embodiments, the substrate 100 may have a structure of an inorganic material between organic materials (e.g., an organic material/an inorganic material/an organic material).

The first buffer layer 111 may increase smoothness of an upper surface of the substrate 100, and the first buffer layer 111 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or a combination thereof.

A barrier layer (not shown) may be further included between the substrate 100 and the first buffer layer 111. The barrier layer may prevent or decrease penetration of impurities from the substrate 100, etc. into the semiconductor layers A1 and A2 (refer to FIG. 5). The barrier layer may include an inorganic material such as oxide or nitride, an organic material, or an organic-inorganic complex material, and may have a single-layer or multilayer structure of an inorganic material and an organic material.

The first connection conductive layer BML1 or the second connection conductive layer BML2 may be disposed on the first buffer layer 111. The first connection conductive layer BML1 may be connected to the data line DL via the first contact hole CNT1 or the second contact hole CNT2. Accordingly, a data signal of the data line DL may be transferred by taking a detour via the first connection conductive layer BML1. The second connection conductive layer BML2 may be connected to the reference voltage line RL via the sixth contact hole CNT6. Accordingly, a pre-charging voltage of the reference voltage line RL may be transferred by taking a detour via the second connection conductive layer BML2.

The second buffer layer 112 may cover the first connection conductive layer BML1 or the second connection conductive layer BML2 and may be formed over the surface (e.g., the entire surface) of the substrate 100. The second buffer layer 112 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or a combination thereof.

The semiconductor layer A2 may be disposed on the second buffer layer 112. The gate electrodes G1 and G2 may be disposed over the semiconductor layer A2 with the gate insulating layer 113 therebetween. The gate electrodes G1 and G2 may include molybdenum (Mo), aluminum (Al), copper (Cu), titanium (Ti), etc. and may have a single-layer or multilayer structure. As an example, the gate electrodes G1 and G2 may include a single Mo layer.

The interlayer insulating layer 115 may cover the gate electrodes G1 and G2. The interlayer insulating layer 115 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or a combination thereof.

The scan line SL and the second lower power line UPL2 may be disposed on the gate insulating layer 113. In this regard, the scan line SL may be disposed over the second connection conductive layer BML2 to overlap the second connection conductive layer BML2. For connection to the data line DL disposed over the scan line SL, a width W2 of the first connection conductive layer BML1 may be greater than a width W1 of the scan line SL.

The second electrode CE2 of the storage capacitor Cst, the source electrode S2, the drain electrode D2, the data line DL, the reference voltage line RL, and the second power line PL2 may be disposed on the interlayer insulating layer 115.

The second electrode CE2 of the storage capacitor Cst, the source electrode S2, the drain electrode D2, the data line DL, the reference voltage line RL, and the second power line PL2 may include a conductive material including molybdenum (Mo), aluminum (Al), copper (Cu), titanium (Ti), etc. and may have a multilayer or single-layer structure including the material described above. As an example, the second electrode CE2, the source electrode S2, the drain electrode D2, the data line DL, the reference voltage line RL, and the second power line PL2 may have a multilayer structure of Aluminum between Titanium (e.g., Ti/Al/Ti).

The source electrodes S1 and S2 and the drain electrode D2 may be connected to the source region or the drain region of the semiconductor layers A1 and A2 via contact holes.

An inorganic protection layer PVX may be provided to cover the second electrode CE2 of the storage capacitor Cst, the source electrode S2, the drain electrode D2, the data line DL, and the reference voltage line RL. The inorganic protection layer PVX, which may be an inorganic insulating layer, may include a single film or multilayer film of silicon nitride and silicon oxide. The inorganic protection layer PVX may at least partially cover the data line DL and wires formed together with the data line DL and thus may prevent the wires from being damaged during a patterning process of the pixel electrode 310.

A planarization layer 117 may be disposed over the drain electrodes D1 and D2, the source electrode S2, the data line DL, the reference voltage line RL, and the second power line PL2, and the organic light-emitting diode OLED may be located on the planarization layer 117.

The planarization layer 117 may include a film including an organic material in a single-layer or multilayer structure. The planarization layer 117 may include benzocyclobutene (BCB), polyimide, hexamethyldisiloxane (HMDSO), a general commodity polymer such as poly(methyl methacrylate) (PMMA) or polystyrene (PS), a polymer derivative having a phenol-based group, an acryl-based polymer, an imide-based polymer, an aryl ether-based polymer, an amide-based polymer, a fluorine-based polymer, a p-xylene based polymer, a vinyl alcohol-based polymer, and a blend thereof. The planarization layer 117 may include an inorganic material. The planarization layer 117 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or a combination thereof. In case that the planarization layer 117 includes an inorganic material, chemical planarization polishing may be performed in some cases. The planarization layer 117 may include both of an organic material and an inorganic material.

In the display area DA of the substrate 100, the organic light-emitting diode OLED may be disposed on the planarization layer 117. The organic light-emitting diode OLED may include the pixel electrode 310, an intermediate layer 320 including an organic emission layer, and the opposite electrode 330.

The planarization layer 117 may include the first via hole VH1 exposing a portion of the drain electrode D1 and the second via hole VH2 exposing a portion of the second power line PL2. The pixel electrode 310 may be connected to the drain electrode D1 of the driving TFT T1 via the first via hole VH1.

The opposite electrode 330 may be connected to the second power line PL2 via the second via hole VH2. Because the intermediate layer 320 of the organic light-emitting diode OLED may have a multilayer structure, at least one layer of the intermediate layer 320 may be disposed in the second via hole VH2 during a process of forming the intermediate layer 320.

Before the opposite electrode 330 may be formed, the intermediate layer 320 that may remain in the second via hole VH2 may be removed by irradiating laser to correspond to the second via hole VH2. Also, after the opposite electrode 330 may be formed, contact characteristics of the opposite electrode 330 and the second power line PL2 may be improved by irradiating laser to the second via hole VH2. Accordingly, the second via hole VH2 may be provided by taking into account an irradiation area of laser. In some embodiments, an area of the second via hole VH2 may be larger than that of the first via hole VH1.

The pixel electrode 310 may be a (semi)light-transmitting electrode or a reflective electrode. In some embodiments, the pixel electrode 310 may include a reflective layer including Ag, Mg, Al, Pt, Pd, Au, Ni, Nd, Ir, Cr, and a compound thereof, and a transparent or semi-transparent electrode layer on the reflective layer. The transparent or semi-transparent electrode layer may include at least one selected from the group including indium tin oxide (ITO), indium zinc oxide (IZO), zinc oxide (ZnO), indium oxide (In₂O₃), indium gallium oxide (IGO), and aluminum zinc oxide (AZO).

A pixel-defining layer 119 may be disposed on the planarization layer 117, and the pixel-defining layer 119 may have a first opening portion OP1 exposing a central portion of the pixel electrode 310 in the display area DA and thus may define an emission area of the organic light-emitting diode OLED. Also, the pixel-defining layer 119 may increase a distance between the edge of the pixel electrode 310 and the opposite electrode 330 disposed over the pixel electrode 310 and thus may prevent the occurrence of an arc, etc. over the edge of the pixel electrode 310.

The pixel-defining layer 119 may include a second opening portion OP2 corresponding to the second via hole VH2 in the planarization layer 117. A portion of the second power line PL2 may be exposed by the second opening portion OP2 and the second via hole VH2, and thus, laser may be irradiated to an area of the second via hole VH2 later.

The pixel-defining layer 119 may be formed by a method such as spin coating, using one or more organic insulating materials selected from the group including polyimide, polyamide, acrylic resin, BCB, and phenolic resin.

The intermediate layer 320 of the organic light-emitting diode OLED may include an organic emission layer. The organic emission layer may include an organic material including a fluorescent or phosphorescent material that may emit red, green, blue, or white light. The organic emission layer may include a low-molecular weight organic material or a polymer organic material, and functional layers such as a hole transport layer (HTL), a hole injection layer (HIL), an electron transport layer (ETL), and an electron injection layer (EIL) may be selectively further disposed under and on the organic emission layer. The intermediate layer 320 may be disposed to correspond to each of pixel electrodes 310. In another embodiment, the intermediate layer 320 may include an integral layer over pixel electrodes 310.

The opposite electrode 330 may be a light-transmitting electrode or a reflective electrode. In some embodiments, the opposite electrode 330 may be a transparent or semitransparent electrode and may include a metallic thin film with a low work function including Li, Ca, LiF/Ca, LiF/Al, Al, Ag, Mg, and a compound thereof. Also, a transparent conductive oxide (TCO) film such as ITO, IZO, ZnO, or In₂O₃ may be further disposed on the metallic thin film. The opposite electrode 330 may be disposed over the display area DA and the non-display area NDA and may be disposed on the intermediate layer 320 and the pixel-defining layer 119. The opposite electrode 330 may be integrally formed in organic light-emitting diodes OLEDs to correspond to pixel electrodes 310.

The opposite electrode 330 may be connected to the second power line PL2 via the second opening portion OP2 and the second via hole VH2.

The organic light-emitting diode OLED may be damaged due to external moisture or oxygen, and thus, a thin film encapsulation layer (not shown) may be disposed thereon to cover and protect such an organic light-emitting device. The thin film encapsulation layer (not shown) may extend beyond the display area DA while covering the display area DA. Such a thin film encapsulation layer may include an inorganic encapsulation layer including at least one inorganic material and an organic encapsulation layer including at least one organic material. In some embodiments, the thin film encapsulation layer may have a stacked structure of an organic encapsulation layer between inorganic encapsulation layers (e.g., a first inorganic encapsulation layer/an organic encapsulation layer/a second inorganic encapsulation layer).

Also, a spacer for preventing mask imprinting may be further included on the pixel-defining layer 119, and various functional layers such as a polarization layer for reducing external light reflection, and a touchscreen layer including a black matrix, a color filter and/or a touch electrode may be provided on the thin film encapsulation layer.

In an embodiment, the first connection conductive layer BML1 overlapping the data line DL may be provided, and thus, even in case that the first cross portion CP1 is cut, a data signal may be transferred. Specifically, the data line DL and the first connection conductive layer BML1 may be connected to each other via the first contact hole CNT1 or the second contact hole CNT2, and thus, a data signal may take a detour. Also, in an embodiment, the first connection conductive layer BML1 may decrease resistance of the data line DL.

Referring to FIG. 5, a display apparatus according to an embodiment may include the substrate 100, and the driving TFT T1 and the sensing TFT T3 disposed over the substrate 100. Also, the display apparatus may include the first lower power line UPL1, the lower reference voltage line URL, and the sensing control line SSL disposed over the substrate 100, and may include the data line DL crossing the sensing control line SSL or the lower reference voltage line URL, the reference voltage line RL, or the first power line PL1. In an embodiment, the display apparatus may include the first connection conductive layer BML1 overlapping a cross portion crossing the sensing control line SSL or the lower reference voltage line URL, and the first connection conductive layer BML1 may be connected to the data line DL via the third contact hole CNT3, the fourth contact hole CNT4, or the fifth contact hole CNT5.

In an embodiment, the display apparatus may further include the storage capacitor Cst connected to the driving TFT T1 and the bias electrode BSM disposed below the driving TFT T1.

The bias electrode BSM may overlap the storage capacitor Cst. Accordingly, the first electrode CE1 and the second electrode CE2 of the storage capacitor Cst may form a first capacitance, and the first electrode CE1 and the bias electrode BSM may form a second capacitance.

The bias electrode BSM may be disposed on the first buffer layer 111 to correspond to the driving TFT T1 and the storage capacitor Cst. Although not shown, the bias electrode BSM may be connected to the source electrode S3 of the sensing TFT T3, and thus, a voltage of the source electrode S3 may be applied thereto. Also, the bias electrode BSM may prevent external light from reaching the semiconductor layer A1. Accordingly, characteristics of the driving TFT T1 may be stabilized.

In an embodiment, the first connection conductive layer BML1 or the third connection conductive layer BML3 may be spaced apart from the bias electrode BSM. The first connection conductive layer BML1 or the third connection conductive layer BML3 may include the same material as the bias electrode BSM. For connection to the data line DL that may be disposed over the sensing control line SSL, a width W4 of the first connection conductive layer BML1 may be greater than a width W3 of the sensing control line SSL.

In an embodiment, the first electrode CE1 of the storage capacitor Cst may be integrally provided with the gate electrode G1. In another embodiment, the first electrode CE1 of the storage capacitor Cst may extend from the gate electrode G1 of the driving TFT T1.

The first power line PL1 may be connected to the source electrode S1 of the driving TFT T1. In an embodiment, the first power line PL1 may be integrally provided with the source electrode S1 of the driving TFT T1.

The data line DL may be disposed on the interlayer insulating layer 115. In an embodiment, the data line DL may overlap the sensing control line SSL or the lower reference voltage line URL. Specifically, the data line DL may cross the sensing control line SSL to have the second cross portion CP2 and may cross the lower reference voltage line URL to have the third cross portion CP3.

In an embodiment, the data line DL may be connected to the first connection conductive layer BML1 via the third contact hole CNT3, the fourth contact hole CNT4, or the fifth contact hole CNT5. The second cross portion CP2 may be disposed between the third contact hole CNT3 and the fourth contact hole CNT4. The third cross portion CP3 may be disposed between the fourth contact hole CNT4 and the fifth contact hole CNT5.

In another embodiment, the fourth contact hole CNT4 may be omitted. In another embodiment, a contact hole connecting the data line DL and the first connection conductive layer BML1 to each other may be further included between the third contact hole CNT3 and the fourth contact hole CNT4.

In an embodiment, the reference voltage line RL may be connected to the third connection conductive layer BML3. Specifically, the reference voltage line RL may be connected to the third connection conductive layer BML3 via the tenth contact hole CNT10.

The first to tenth contact holes CNT1 to CNT10 described above may be disposed as respective through holes in the second buffer layer 112, the gate insulating layer 113, and the interlayer insulating layer 115 of FIG. 4 or FIG. 5.

Hereinafter, a repairing method will be described where a first wire and a second wire of the display apparatus described above may be short-circuited.

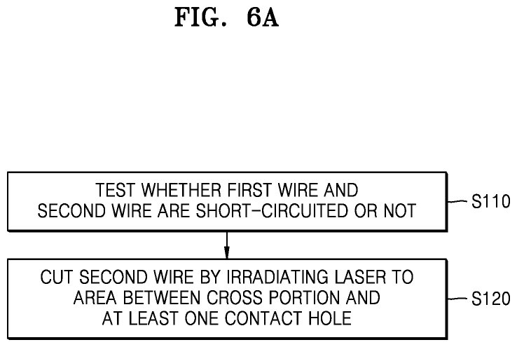

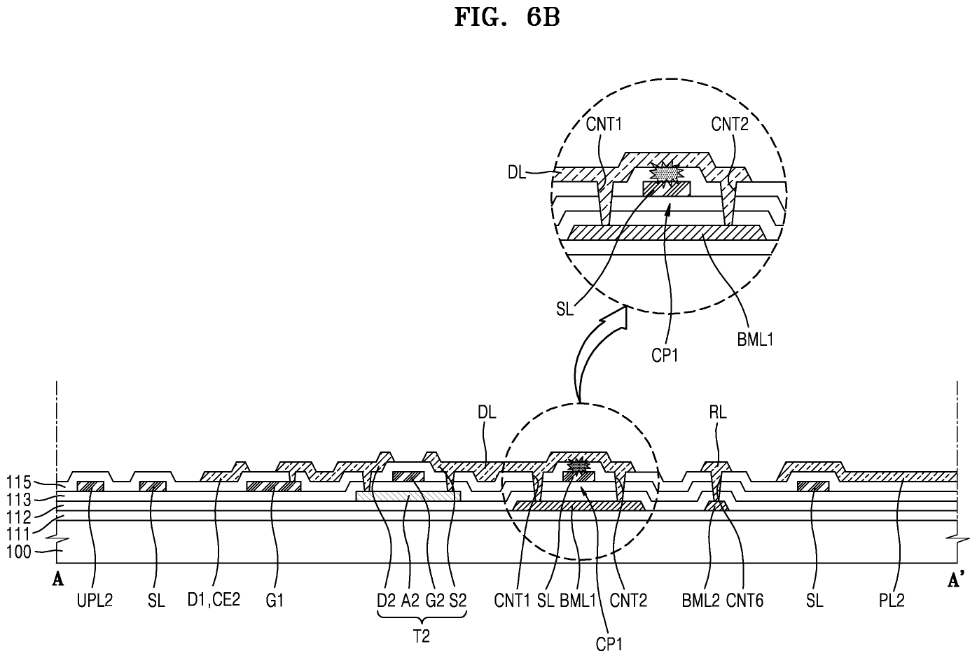

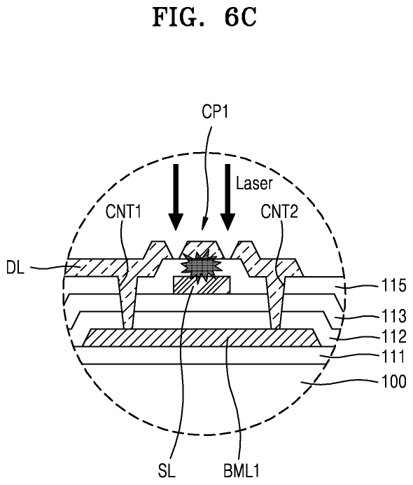

FIG. 6A is a flowchart showing a method of repairing a display apparatus, according to an embodiment. FIG. 6B is a schematic cross-sectional view showing an operation of testing whether a first wire and a second wire may be short-circuited or not, according to an embodiment. FIG. 6C is a schematic enlarged view showing an operation of cutting a second wire, according to an embodiment.

In FIGS. 6B and 6C, reference numerals that are the same as those in FIG. 4 denote the same elements, and thus, a repeated description thereof is omitted.

Referring to FIG. 6A, a method of repairing a display apparatus may include an operation S110 of testing whether a first wire and a second wire may be short-circuited or not and an operation S120 of cutting the second wire by irradiating laser to an area between a cross portion and at least one contact hole.

The first wire may be the scan line SL, the sensing control line SSL, the first lower power line UPL1, the second lower power line UPL2, or the lower reference voltage line URL extending in the first direction DR1, which have been described with reference to FIG. 3. The second wire may be the data line DL, the reference voltage line RL, the first power line PL1, or the second power line PL2.

The cross portion may be any of the first to sixth cross portions CP1 to CP6 described with reference to FIG. 3.

The at least one contact hole may be any of the first to tenth contact holes CNT1 to CNT10 described with reference to FIG. 3.

In case that the first wire and the second wire may be short-circuited in the cross portion where the first wire and the second wire may cross each other, a short-circuit may be prevented by cutting the second wire. Specifically, the second wire may be cut by irradiating laser to an area between the cross portion and the at least one contact hole.

Referring to FIG. 6B, the data line DL and the scan line SL may cross each other to have the first cross portion CP1. In this regard, whether the data line DL and the scan line SL may be short-circuited or not may be tested.

Referring to FIG. 6C, in case that the data line DL and the scan line SL may be short-circuited, laser may be irradiated to an area between the first cross portion CP1 and the first contact hole CNT1 and/or an area between the first cross portion CP1 and the second contact hole CNT2. Accordingly, the data line DL may be cut.

In an embodiment, a data signal may be transferred to a pixel by taking a detour via the first connection conductive layer BML1 because the data line DL is connected to the first connection conductive layer BML1 via the first contact hole CNT1 or the second contact hole CNT2. Accordingly, improved reliability of the display apparatus may be obtained.

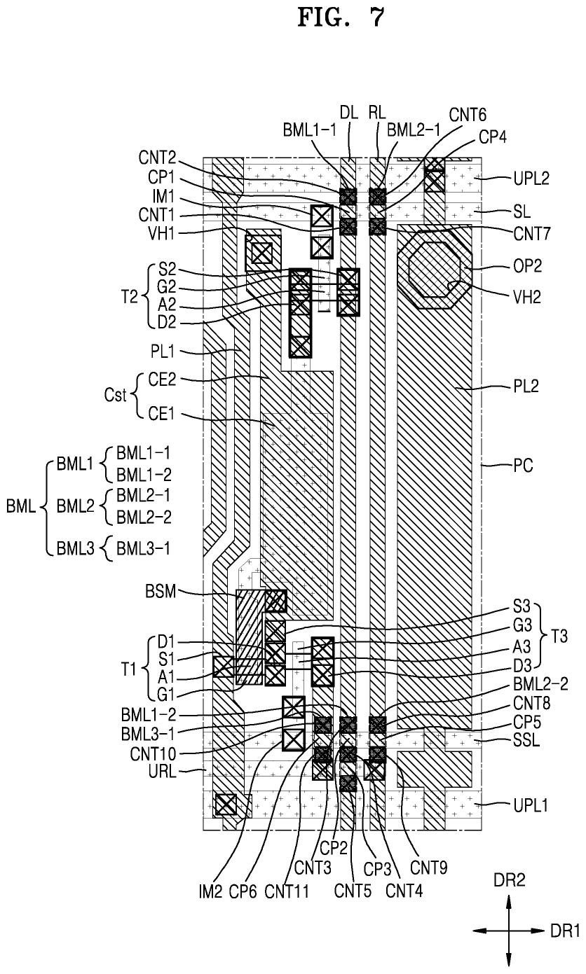

FIG. 7 is a schematic representation illustrating locations of TFTs and a capacitor Cst included in a pixel circuit PC according to another embodiment. In FIG. 7, reference numerals that are the same as those in FIG. 3 denote the same elements, and thus, a repeated description thereof is omitted.

Referring to FIG. 7, the pixel circuit PC of a display apparatus according to an embodiment may be connected to the scan line SL, the sensing control line SSL, the first lower power line UPL1, the second lower power line UPL2, and the lower reference voltage line URL extending in the first direction DR1.

In an embodiment, the connection conductive layer BML may have an island shape. Specifically, the first connection conductive layer BML1 may include a first portion BML1-1 or a second portion BML1-2. The second connection conductive layer BML2 may include a third portion BML2-1 or a fourth portion BML2-2. The third connection conductive layer BML3 may include a fifth portion BML3-1. The first to fifth portions BML1-1 to BML3-1 may have an island shape. Accordingly, the first to fifth portions BML1-1 to BML3-1 may be spaced apart from one another.

The first portion BML1-1 may overlap the first cross portion CP1 where the data line DL and the scan line SL may cross each other. The first portion BML1-1 may be connected to the data line DL via the first contact hole CNT1 or the second contact hole CNT2. In this regard, a length of the first portion BML1-1 in the second direction DR2 may be greater than a width of the scan line SL in the second direction DR2.

The second portion BML1-2 may overlap the second cross portion CP2 where the data line DL and the sensing control line SSL may cross each other. Also, the second portion BML1-2 may overlap the third cross portion CP3 where the data line DL and the lower reference voltage line URL may cross each other. The second portion BML1-2 may be connected to the data line DL via the third contact hole CNT3, the fourth contact hole CNT4, or the fifth contact hole CNT5. In this regard, a length of the second portion BML1-2 in the second direction DR2 may be greater than a width of the sensing control line SSL or the lower reference voltage line URL in the second direction DR2. In another embodiment, some of the third contact hole CNT3, the fourth contact hole CNT4, and the fifth contact hole CNT5 may be omitted. In another embodiment, the second portion BML1-2 may include a first area overlapping the second cross portion CP2 and a second area overlapping the third cross portion CP3 and spaced apart from the first area. In this regard, a contact hole connected to the data line DL may be further included between the third contact hole CNT3 and the fourth contact hole CNT4.

The third portion BML2-1 may overlap the fourth cross portion CP4 where the reference voltage line RL and the scan line SL may cross each other. The third portion BML2-1 may be connected to the reference voltage line RL via the sixth contact hole CNT6 or the seventh contact hole CNT7. In this regard, a length of the third portion BML2-1 in the second direction DR2 may be greater than a width of the scan line SL in the second direction DR2.

The fourth portion BML2-2 may overlap the fifth cross portion CP5 where the reference voltage line RL and the sensing control line SSL may cross each other. The fourth portion BML2-2 may be connected to the reference voltage line RL via the eighth contact hole CNT8 or the ninth contact hole CNT9. In this regard, a length of the fourth portion BML2-2 in the second direction DR2 may be greater than a width of the sensing control line SSL in the second direction DR2.

The fifth portion BML3-1 may overlap the sixth cross portion CP6 where the second intermediate conductive layer IM2 and the sensing control line SSL may cross each other. The fifth portion BML3-1 may be connected to the second intermediate conductive layer IM2 via the tenth contact hole CNT10 or the eleventh contact hole CNT11. In this regard, a length of the fifth portion BML3-1 in the second direction DR2 may be greater than a width of the sensing control line SSL in the second direction DR2.

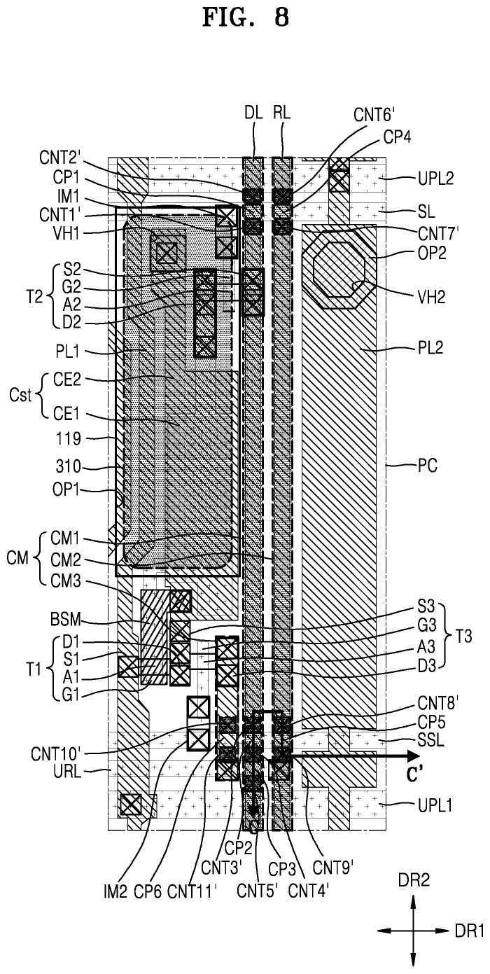

FIG. 8 is a schematic representation illustrating locations of TFTs and a capacitor Cst included in the pixel circuit PC according to another embodiment. In FIG. 8, reference numerals that are the same as those in FIG. 3 denote the same elements, and thus, a repeated description thereof is omitted.

Referring to FIG. 8, the pixel circuit PC of a display apparatus according to an embodiment may be connected to the scan line SL, the sensing control line SSL, the first lower power line UPL1, the second lower power line UPL2, and the lower reference voltage line URL extending in the first direction DR1. The pixel electrode 310 may be connected to the second electrode CE2 of the storage capacitor Cst via the first via hole VH1. Also, the pixel-defining layer 119 may include the first opening portion OP1 exposing a central portion of the pixel electrode 310 in the display area DA.

In an embodiment, an upper conductive layer CM may be disposed over the second wire. For example, the upper conductive layer CM may be disposed over the data line DL, the reference voltage line RL, the first power line PL1, and the second power line PL2.

In an embodiment, the upper conductive layer CM may be disposed on the same layer as the pixel electrode 310 and may be spaced apart from the pixel electrode 310. Specifically, the upper conductive layer CM may be spaced apart from the pixel electrode 310 in the first direction DR1 or the second direction DR2. In an embodiment, the upper conductive layer CM may include the same material as the pixel electrode 310.

In an embodiment, the upper conductive layer CM may include a first upper conductive layer CM1, a second upper conductive layer CM2, and a third upper conductive layer CM3. The first upper conductive layer CM1, the second upper conductive layer CM2, and the third upper conductive layer CM3 may be spaced apart from one another. For example, the first upper conductive layer CM1, the second upper conductive layer CM2, and the third upper conductive layer CM3 may be spaced apart from one another in the first direction DR1.

The first upper conductive layer CM1 may overlap the data line DL. In an embodiment, the first upper conductive layer CM1 may extend in the second direction DR2 while overlapping the data line DL. For example, the first upper conductive layer CM1 may extend while continuously overlapping the data line DL.

In an embodiment, the first upper conductive layer CM1 may overlap the first cross portion CP1 where the data line DL and the scan line SL may cross each other. The first upper conductive layer CM1 may overlap the second cross portion CP2 where the data line DL and the sensing control line SSL may cross each other. Also, the first upper conductive layer CM1 may overlap the third cross portion CP3 where the data line DL and the lower reference voltage line URL may cross each other.

The first upper conductive layer CM1 may be connected to the data line DL via at least one connection contact hole. In an embodiment, the first upper conductive layer CM1 may be connected to the data line DL via a first contact hole CNT1′ and a second contact hole CNT2′. In this regard, the first cross portion CP1 may be disposed between the first contact hole CNT1′ and the second contact hole CNT2′. Accordingly, the data signal Dm of the data line DL may be transferred by taking a detour via the first upper conductive layer CM1. As another example, the first upper conductive layer CM1 may be connected to the data line DL via a third contact hole CNT3′, a fourth contact hole CNT4′, or a fifth contact hole CNT5′. In this regard, the second cross portion CP2 may be disposed between the third contact hole CNT3′ and the fourth contact hole CNT4′. The third cross portion CP3 may be disposed between the fourth contact hole CNT4′ and the fifth contact hole CNT5′.

In another embodiment, some of the first to fifth contact holes CNT1′ to CNT5′ may be omitted. For example, the fourth contact hole CNT4′ from among the third contact hole CNT3′, the fourth contact hole CNT4′, and the fifth contact hole CNT5′ may be omitted. In another embodiment, a contact hole may be further included between the third contact hole CNT3′ and the fourth contact hole CNT4′.

The second upper conductive layer CM2 may overlap the reference voltage line RL. In an embodiment, the second upper conductive layer CM2 may extend in the second direction DR2 while overlapping the reference voltage line RL. For example, the second upper conductive layer CM2 may extend while continuously overlapping the reference voltage line RL.

In an embodiment, the second upper conductive layer CM2 may overlap the fourth cross portion CP4 where the reference voltage line RL and the scan line SL may cross each other. Also, the second upper conductive layer CM2 may overlap the fifth cross portion CP5 where the reference voltage line RL and the sensing control line SSL may cross each other.

The second upper conductive layer CM2 may be connected to the reference voltage line RL via at least one connection contact hole. For example, the second upper conductive layer CM2 may be connected to the reference voltage line RL via a sixth contact hole CNT6′ or a seventh contact hole CNT7′. In this regard, the fourth cross portion CP4 may be disposed between the sixth contact hole CNT6′ and the seventh contact hole CNT7′. As another example, the second upper conductive layer CM2 may be connected to the reference voltage line RL via an eighth contact hole CNT8′ or a ninth contact hole CNT9′. In this regard, the fifth cross portion CP5 may be disposed between the eighth contact hole CNT8′ and the ninth contact hole CNT9′. Accordingly, a pre-charging voltage of the reference voltage line RL may be transferred by taking a detour via the second upper conductive layer CM2.

The third upper conductive layer CM3 may overlap the second intermediate conductive layer IM2. In an embodiment, the third upper conductive layer CM3 may extend in the second direction DR2 while overlapping the second intermediate conductive layer IM2. For example, the third upper conductive layer CM3 may extend while continuously overlapping the second intermediate conductive layer IM2. The third upper conductive layer CM3 may overlap the sixth cross portion CP6 where the second intermediate conductive layer IM2 and the sensing control line SSL may cross each other.

The third upper conductive layer CM3 may be connected to the second intermediate conductive layer IM2 via at least one connection contact hole. For example, the third upper conductive layer CM3 may be connected to the second intermediate conductive layer IM2 via a tenth contact hole CNT10′ or an eleventh contact hole CNT11′. In this regard, the sixth cross portion CP6 may be disposed between the tenth contact hole CNT10′ and the eleventh contact hole CNT11′. Accordingly, a pre-charging voltage of the reference voltage line RL may be transferred by taking a detour via the third upper conductive layer CM3.

The upper conductive layer CM overlapping the second wire may be provided as described above to cut the second wire in case that the first wire and the second wire may be short-circuited. In case that the first wire and the second wire may be short-circuited, a cross portion where the first wire and the second wire may cross each other may be cut. In this regard, in case that the second wire may not have a mesh structure as the first power line PL1 or the second power line PL2 does, no signal may be transferred to the pixel circuit PC. In an embodiment, the upper conductive layer CM overlapping the second wire may be provided, and thus, even in case that the cross portion is cut, signals may be transferred to the pixel circuit PC. Specifically, the second wire and the upper conductive layer CM may be connected to each other via at least one contact hole, and thus, a signal may take a detour. In an embodiment, the upper conductive layer CM may be formed simultaneously with the pixel electrode 310, and thus, no mask may be additionally used. Also, in an embodiment, the upper conductive layer CM may decrease resistance of the second wire.

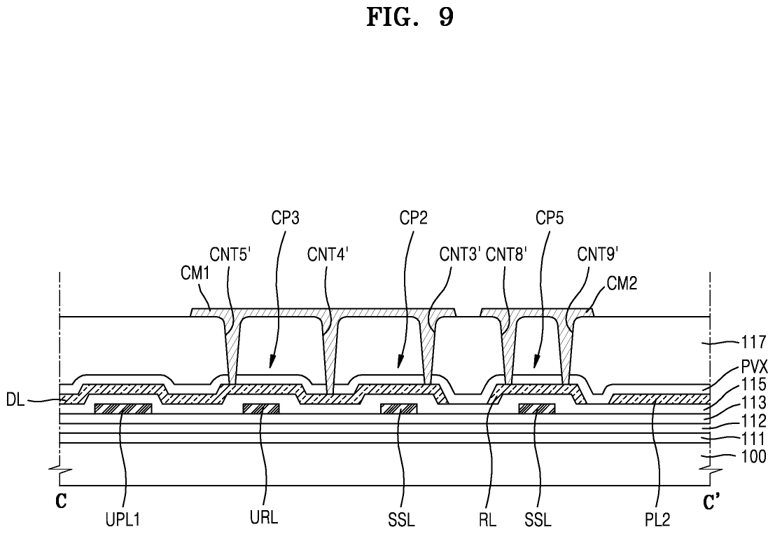

FIG. 9 is a schematic cross-sectional view taken along line C-C′ of FIG. 8. In FIG. 9, reference numerals that are the same as those in FIG. 4 or FIG. 5 denote the same elements, and thus, a repeated description thereof is omitted.

Referring to FIG. 9, the first lower power line UPL1, the lower reference voltage line URL, and the sensing control line SSL disposed over the substrate 100 may be included, and the data line DL crossing the lower reference voltage line URL or the sensing control line SSL and the reference voltage line RL crossing the sensing control line SSL may be included.

In an embodiment, the first upper conductive layer CM1 may overlap the second cross portion CP2 where the sensing control line SSL and the data line DL may cross each other. Also, the first upper conductive layer CM1 may overlap the third cross portion CP3 where the lower reference voltage line URL and the data line DL may cross each other. In an embodiment, the second upper conductive layer CM2 may overlap the fifth cross portion CP5 where the sensing control line SSL and the reference voltage line RL may cross each other.

The first upper conductive layer CM1 and the second upper conductive layer CM2 may be disposed on the planarization layer 117. Specifically, the first upper conductive layer CM1 and the second upper conductive layer CM2 may be disposed on the same layer as a pixel electrode.

The first upper conductive layer CM1 may be connected to the data line DL via at least one connection contact hole. In an embodiment, the first upper conductive layer CM1 may be connected to the data line DL via the third contact hole CNT3′, the fourth contact hole CNT4′, or the fifth contact hole CNT5′. In this regard, the second cross portion CP2 may be disposed between the third contact hole CNT3′ and the fourth contact hole CNT4′. The third cross portion CP3 may be disposed between the fourth contact hole CNT4′ and the fifth contact hole CNT5′. Accordingly, a data signal of the data line DL may be transferred by taking a detour via the first upper conductive layer CM1.

In another embodiment, some of the third to fifth contact holes CNT3′ to CNT5′ may be omitted. For example, the fourth contact hole CNT4′ from among the third contact hole CNT3′, the fourth contact hole CNT4′, and the fifth contact hole CNT5′ may be omitted.

The second upper conductive layer CM2 may be connected to the reference voltage line RL via at least one connection contact hole. As another example, the second upper conductive layer CM2 may be connected to the reference voltage line RL via the eighth contact hole CNT8′ or the ninth contact hole CNT9′. In this regard, the fifth cross portion CP5 may be disposed between the eighth contact hole CNT8′ and the ninth contact hole CNT9′. Accordingly, a pre-charging voltage of the reference voltage line RL may be transferred by taking a detour via the second upper conductive layer CM2.

The first to tenth contact holes CNT1′ to CNT10′ described above may be disposed as respective through holes in the inorganic protection layer PVX and the planarization layer 117.

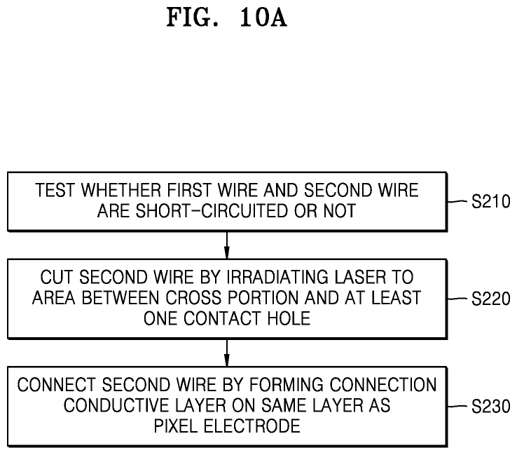

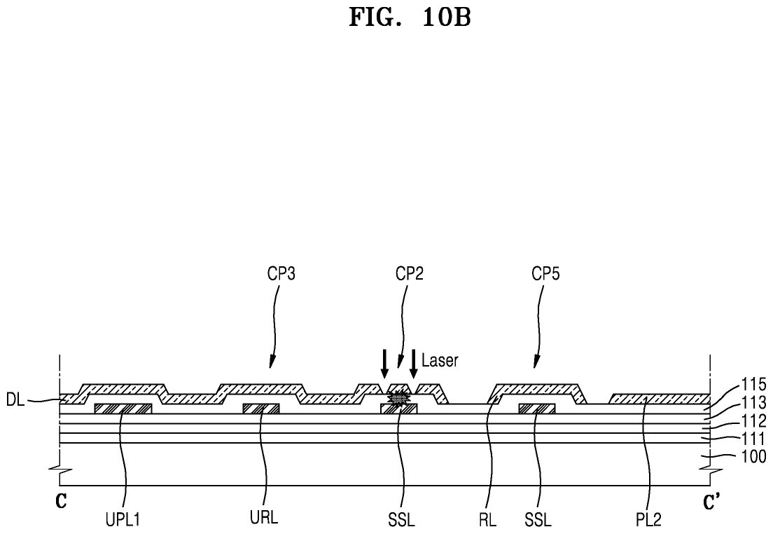

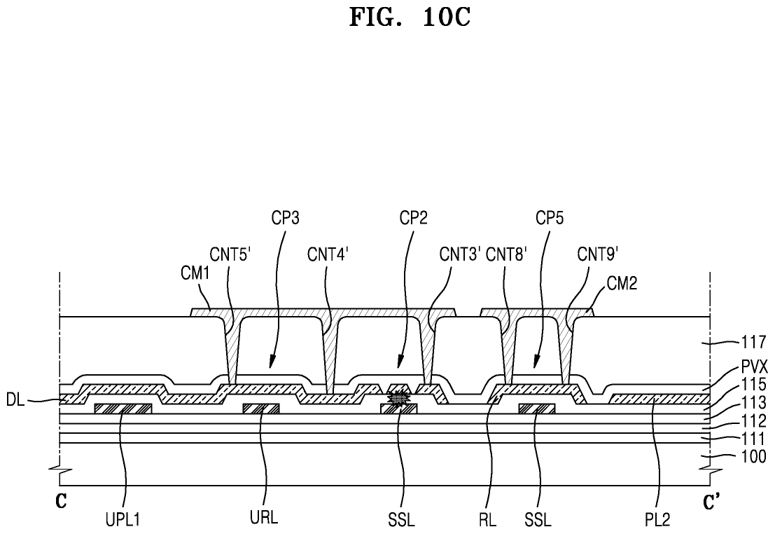

FIG. 10A is a flowchart showing a method of repairing a display apparatus, according to another embodiment. FIG. 10B is a schematic cross-sectional view showing an operation of cutting a second wire, according to another embodiment. FIG. 10C is a schematic cross-sectional view showing an operation of forming a connection conductive layer, according to another embodiment.

In FIGS. 10B and 10C, reference numerals that are the same as those in FIG. 9 denote the same elements, and thus, a repeated description thereof is omitted.

Referring to FIG. 10A, a method of repairing a display apparatus may include an operation S210 of testing whether a first wire and a second wire may be short-circuited or not, an operation S220 of cutting the second wire by irradiating laser to an area between a cross portion and at least one contact hole, and an operation S230 of connecting the second wire by forming a connection conductive layer on the same layer as a pixel electrode.

The first wire may be the scan line SL, the sensing control line SSL, the first lower power line UPL1, the second lower power line UPL2, or the lower reference voltage line URL extending in the first direction DR1, which have been described with reference to FIG. 8. The second wire may be the data line DL, the reference voltage line RL, the first power line PL1, or the second power line PL2.

The cross portion may be any of the first to sixth cross portions CP1 to CP6 described with reference to FIG. 8.

The at least one contact hole may be any of the first to tenth contact holes CNT1′ to CNT10′ described with reference to FIG. 8.

In case that the first wire and the second wire may be short-circuited in the cross portion where the first wire and the second wire may cross each other, a short-circuit may be prevented by cutting the second wire. Specifically, the second wire may be cut by irradiating laser to an area between the cross portion and the at least one contact hole.

Referring to FIG. 10B, the data line DL and the sensing control line SSL may cross each other to have the second cross portion CP2. Whether the data line DL and the sensing control line SSL may be short-circuited or not may be tested. In this regard, in case that the data line DL and the sensing control line SSL may be short-circuited, laser may be irradiated to an area between the second cross portion CP2 and the third contact hole CNT3′ and/or an area between the second cross portion CP2 and the fourth contact hole CNT4′. Accordingly, the data line DL may be cut.

Referring to FIG. 10C, after the second wire may be cut, the second wire may be connected by forming a connection conductive layer on the same layer as the pixel electrode. For example, after the data line DL may be cut, the first upper conductive layer CM1 may be formed on the planarization layer 117. The first upper conductive layer CM1 may be connected to the data line DL via the third contact hole CNT3′ or the fourth contact hole CNT4′. Accordingly, a data signal of the data line DL may be transferred to a pixel by taking a detour via the first upper conductive layer CM1. Accordingly, improved reliability of the display apparatus may be obtained.

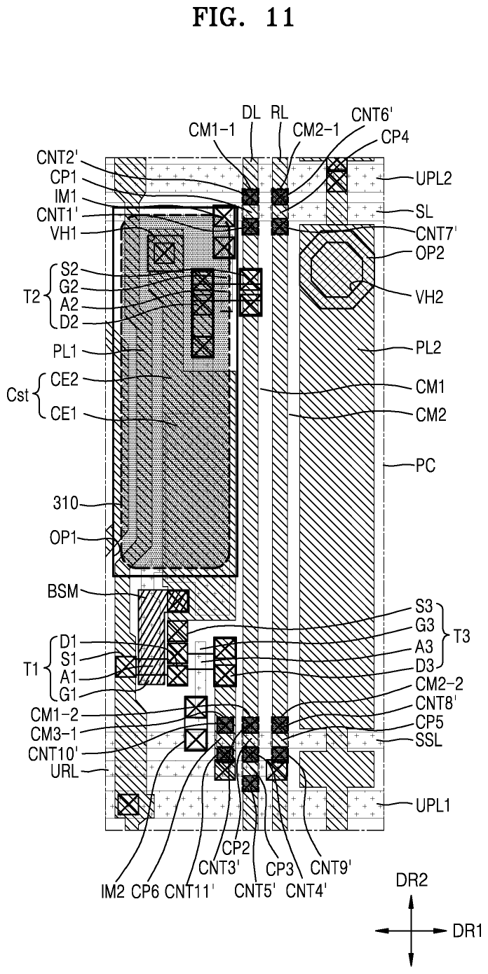

FIG. 11 is a schematic representation illustrating locations of TFTs and a capacitor Cst included in a pixel circuit PC according to another embodiment. In FIG. 11, reference numerals that are the same as those in FIG. 8 denote the same elements, and thus, a repeated description thereof is omitted.

Referring to FIG. 11, the pixel circuit PC of a display apparatus according to an embodiment may be connected to the scan line SL, the sensing control line SSL, the first lower power line UPL1, the second lower power line UPL2, and the lower reference voltage line URL extending in the first direction DR1.

In an embodiment, the upper conductive layer CM may have an island shape. Specifically, the first upper conductive layer CM1 may include a first upper portion CM1-1 or a second upper portion CM1-2. The second upper conductive layer CM2 may include a third upper portion CM2-1 or a fourth upper portion CM2-2. The third upper conductive layer CM3 may include a fifth upper portion CM3-1. The first to fifth upper portions CM1-1 to CM3-1 may have an island shape. Accordingly, the first to fifth upper portions CM1-1 to CM3-1 may be spaced apart from one another.

The first upper portion CM1-1 may overlap the first cross portion CP1 where the data line DL and the scan line SL may cross each other. The first upper portion CM1-1 may be connected to the data line DL via the first contact hole CNT1′ or the second contact hole CNT2′. In this regard, a length of the first upper portion CM1-1 in the second direction DR2 may be greater than a width of the scan line SL in the second direction DR2.

The second upper portion CM1-2 may overlap the second cross portion CP2 where the data line DL and the sensing control line SSL may cross each other. Also, the second upper portion CM1-2 may overlap the third cross portion CP3 where the data line DL and the lower reference voltage line URL may cross each other. The second upper portion CM1-2 may be connected to the data line DL via the third contact hole CNT3′, the fourth contact hole CNT4′, or the fifth contact hole CNT5′. In this regard, a length of the second upper portion CM1-2 in the second direction DR2 may be greater than a width of the sensing control line SSL or the lower reference voltage line URL in the second direction DR2. In another embodiment, some of the third contact hole CNT3′, the fourth contact hole CNT4′, and the fifth contact hole CNT5′ may be omitted. In another embodiment, the second upper portion CM1-2 may include a first area overlapping the second cross portion CP2 and a second area overlapping the third cross portion CP3 and spaced apart from the first area. In this regard, a contact hole connected to the data line DL may be further included between the third contact hole CNT3′ and the fourth contact hole CNT4′.

The third upper portion CM2-1 may overlap the fourth cross portion CP4 where the reference voltage line RL and the scan line SL may cross each other. The third upper portion CM2-1 may be connected to the reference voltage line RL via the sixth contact hole CNT6′ or the seventh contact hole CNT7′. In this regard, a length of the third upper portion CM2-1 in the second direction DR2 may be greater than a width of the scan line SL in the second direction DR2.

The fourth upper portion CM2-2 may overlap the fifth cross portion CP5 where the reference voltage line RL and the sensing control line SSL may cross each other. The fourth upper portion CM2-2 may be connected to the reference voltage line RL via the eighth contact hole CNT8′ or the ninth contact hole CNT9′. In this regard, a length of the fourth upper portion CM2-2 in the second direction DR2 may be greater than a width of the sensing control line SSL in the second direction DR2.

The fifth upper portion CM3-1 may overlap the sixth cross portion CP6 where the second intermediate conductive layer IM2 and the sensing control line SSL may cross each other. The fifth upper portion CM3-1 may be connected to the second intermediate conductive layer IM2 via the tenth contact hole CNT10′ or the eleventh contact hole CNT11′. In this regard, a length of the fifth upper portion CM3-1 in the second direction DR2 may be greater than a width of the sensing control line SSL in the second direction DR2.

According to one or more embodiments, a display apparatus may include a conductive layer overlapping a cross portion where signal wires may cross each other, the conductive layer enabling a detour for a signal and thus improve the reliability of the display apparatus.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and equivalents thereof.

What is claimed is:

1. A display apparatus comprising:
a substrate including a display area and a non-display area;
a display element over the display area;
a thin film transistor disposed between the substrate and the display element and connected to the display element;
a first wire connected to the thin film transistor and extending in a first direction;
a second wire disposed above the first wire and extending in a second direction crossing the first direction;
a connection conductive layer overlapping a cross portion where the first wire and the second wire cross each other;
an insulating layer disposed between the connection conductive layer and the second wire; and
at least one connection contact hole defined in the insulating layer, the at least one connection contact hole connecting the connection conductive layer and the second wire.

2. The display apparatus of claim 1, wherein the connection conductive layer is between the substrate and the first wire.

3. The display apparatus of claim 2, further comprising a buffer layer disposed between the connection conductive layer and the first wire.

4. The display apparatus of claim 1, wherein the display apparatus further comprises a bias electrode disposed between the substrate and a semiconductor layer and overlapping the semiconductor layer, wherein
the thin film transistor includes the semiconductor layer, and
the connection conductive layer and the bias electrode are disposed on a same layer.

5. The display apparatus of claim 4, wherein the connection conductive layer is spaced apart from the bias electrode.

6. The display apparatus of claim 1, wherein the connection conductive layer is disposed over the second wire.

7. The display apparatus of claim 6, wherein
the display element comprises a pixel electrode and an opposite electrode, and
the connection conductive layer and the pixel electrode are disposed on a same layer.

8. The display apparatus of claim 7, wherein the connection conductive layer is spaced apart from the pixel electrode.

9. The display apparatus of claim 6, further comprising a planarization layer between the display element and the thin film transistor,
wherein the connection conductive layer is on the planarization layer.

10. The display apparatus of claim 1, wherein the thin film transistor comprises a gate electrode, a source electrode, and a drain electrode,
wherein the first wire is connected to the gate electrode.

11. The display apparatus of claim 10, wherein the second wire is connected to the source electrode or the drain electrode.

12. The display apparatus of claim 1, wherein the connection conductive layer extends in the second direction.

13. The display apparatus of claim 1, wherein the connection conductive layer comprises an island shape.

14. The display apparatus of claim 1, wherein a length of the connection conductive layer in the second direction is greater than a length of the cross portion in the second direction.

15. The display apparatus of claim 1, wherein the at least one connection contact hole comprises a first contact hole and a second contact hole,
wherein the cross portion is between the first contact hole and the second contact hole.

16. The display apparatus of claim 1, wherein the second wire comprises a data line.

17. The display apparatus of claim 1, further comprising an inorganic protection layer covering the second wire.

18. A method of repairing a display apparatus, wherein the display apparatus comprises:
a substrate;
a first wire extending over the substrate in a first direction;
a second wire disposed above the first wire and crossing the first wire;
a connection conductive layer overlapping a cross portion where the first wire and the second wire cross each other;
an insulating layer between the connection conductive layer and the second wire; and
at least one connection contact hole in the insulating layer, the connection conductive layer is connected to the second wire via the at least one connection contact hole,
wherein the method comprises cutting the second wire by irradiating laser to an area between the cross portion and the at least one connection contact hole.

19. The method of claim 18, further comprising:
before the cutting of the second wire, testing whether the first wire and the second wire are short-circuited or not.

20. The method of claim 18, wherein the display apparatus comprises a display element including a pixel electrode and an opposite electrode, wherein the method further comprises:
after the cutting of the second wire, connecting the second wire by forming the connection conductive layer and the pixel electrode on a same layer.
